(19) United States
(12) Patent Application Publication
(10) Pub. No.: US 2019/0344154 A1
(43) Pub. Date: Nov. 14, 2019

(54) INTELLIGENT ROLLER SKATING SHOES

(71) Applicant: Kuiyin ZHU, Shanghai (CN)

(72) Inventor: Kuiyin ZHU, Shanghai (CN)

(21) Appl. No.: 16/406,014

(22) Filed: May 8, 2019

(30) Foreign Application Priority Data
May 10, 2018 (CN) 201810442294.1

(51) Int. Cl. A63C 17/26; H05K 1/18; H05K 7/14; A63C 17/06; G01R 33/09; G01D 5/16; H04M 1/725; G08B 21/02; G01P 1/07

(52) U.S. Cl. CPC A63C 17/26; H05K 1/18; H05K 7/1427; A63C 17/068; G01R 33/098; G01D 5/16; A63C 2203/22; G08B 21/0266; G01P 1/07; H05K 2201/10151; H05K 2201/10159; A63C 2203/24; H04M 1/7253

(57) ABSTRACT

The present invention discloses a pair of intelligent roller skating shoes; each comprising a shoe body, a wheel carrier, and an intelligent module, wherein the wheel carrier comprises a connecting frame connected to the shoe body and wheels arranged on the connecting frame, one wheel is provided with a magnet, the intelligent module comprises a circuit board and a terminal device connected by wireless signal transmission, the circuit board comprises a power unit as well as a magnetic sensor and a wireless transmission unit connected to the power unit by circuits, the magnet can respond to the magnetic sensor. The roller skating data obtained by sensing is transmitted to the terminal device by the wireless transmission unit, so that the activity data of the roller skating shoes can be detected to visually learn the exercise situation and also increase the roller skating fun.

### BACKGROUND OF THE INVENTION

The present invention relates to a pair of roller skating shoes, and particularly relates to a pair of intelligent roller skating shoes.

As a leisure and entertainment article, roller skating shoes are very popular among children and young people to feel the skating fun. Roller skating is also a fun way to exercise balance and control leg muscles, so many parents are willing to let children learn to roller skating. Children are also the biggest group to play roller skating. For children's roller skating, children feel the skating fun, while parents pay attention to the monitoring of activity range. The roller skating shoes currently on the market are ordinary skates without other functions. The changes in roller skating shoes for so many years are limited to the appearance, whereas the structure is changed little. Some manufacturers and hobbyists also raise many improvements on the roller skating shoes, e.g., the realization of some intelligent effects. However, these intelligent effects are only some simple intelligent effects, e.g., playing music, lighting, gravity sensing, etc. Many of them just propose relatively preliminary technical solutions, do not give technical solutions of specific structures, and are not practically applied to the roller skating shoes, even some technical solutions are actually difficult to implement, and the improvement on the skating fun and the monitoring of activity range is not reflected.

### BRIEF SUMMARY OF THE INVENTION

The present invention is directed to provide a pair of intelligent roller skating shoes capable of detecting roller skating data to enhance skating fun and monitoring of activity range.

To attain this, the present invention is adopts the following technical scheme:

The present invention discloses a pair of intelligent roller skating shoes, each comprising a shoe body, a wheel carrier, and an intelligent module, wherein the wheel carrier comprises a connecting frame connected to the shoe body and wheels arranged on the connecting frame, one wheel is provided with a magnet, the intelligent module comprises a circuit board and a terminal device connected by wireless signal transmission, the circuit board comprises a power unit as well as a magnetic sensor and a wireless transmission unit connected to the power unit by circuits, the magnetic sensor is connected to the wireless transmission unit by a circuit, the circuit board is arranged on the connecting frame, the magnetic sensor is arranged corresponding to the magnet of the wheel, and the magnet can respond to the magnetic sensor when the wheel rotates.

The wireless transmission unit is a low power consumption Bluetooth chip, the magnetic sensor is a TMR sensor, the circuit board further comprises a memory and an acceleration sensor, the memory is connected to the power unit and the wireless transmission unit by circuits, and the acceleration sensor is connected to the power unit and the wireless transmission unit by circuits.

The terminal device comprises a Bluetooth transmission unit, an interactive operation screen, an intelligent operating system, and a roller skating shoes application software installed and operated in the intelligent operating system, the roller skating shoes application software displays and interacts an operation through the interactive operation screen, the roller skating shoes application software is connected with the low power consumption Bluetooth chip through the Bluetooth transmission unit to transmit data so as to acquire roller skating data of the roller skating shoes, the roller skating shoes application software comprises a data configuration unit, an electronic fence unit and a module setting unit, and the electronic fence unit realizes a fence function by acquiring the signal strength of connection between the Bluetooth transmission unit and the low power consumption Bluetooth chip.

The circuit board further comprises a buzzer connected to the power unit and the wireless transmission unit by circuits.

The roller skating shoes application software further comprises an electronic pet unit.

The wheel comprises an axis ring and a rubber rim, a fixed arrangement structure for fixedly placing the magnet is arranged on the middle section of the peripheral surface of the axis ring, the rubber rim is injection-molded on the axis ring, and the magnet is embedded into the rubber rim.

Wherein the wheel carrier is an in-line wheel carrier, the magnet is arranged on the wheel closest to the rear end of the roller skating shoes, the rear end of the connecting frame is extended to form a mounting cavity for fixedly mounting the circuit board, and a sealing cover for sealing and covering the circuit board is arranged on the mounting cavity.

A detachable mounting shell is embedded into the mounting cavity, the circuit board is fixedly embedded in the mounting shell, and the sealing cover covers the mounting shell.

The mounting shell is provided with a through hole, a side wall of the mounting cavity is provided with a mounting hole corresponding to the through hole, the mounting shell passes through the mounting hole and the through hole through a pin and is fixedly arranged in the mounting cavity, the mounting shell and the sealing cover are sealed by a sealing ring, and the mounting shell and the sealing cover are fixedly connected by screws.

A positioning structure and a connecting structure for quick disassembly and assembly, which match with each other, are respectively arranged in the mounting cavity and on the mounting shell, and the mounting shell or the sealing cover is provided with a clamping structure.

By adopting the above technical solution, the present invention has the following beneficial effects: when the roller skating shoes of the above structure are used, the wheels rotate, the magnets on the wheels follow to circle, the magnets and the magnetic sensors on the circuit boards can reach a fixed angle in each circle and respond to each other to sense the number of circling, this sensing method is realized by magnetic field induction, and no substantial connection is between the magnet and the magnetic sensor; unlike other substantial circuit connection or contact sensing method having the problems that the connection is easily damaged to affect the sensing and the structure is complicated, the response between the magnets and the magnetic sensors in the present invention is not damaged, the service life is longer, the sensing is more accurate, the structural arrangement of the roller skating shoes is not affected, and the roller skating shoes are more compact in appearance; the roller skating data obtained by sensing is transmitted to the terminal device by the wireless transmission unit, so that the activity data of the roller skating shoes can be detected to visually learn the exercise situation and also increase the roller skating fun.

Ultra-low power operation can be realized by using the low power consumption Bluetooth chip (with the characteristics of low power consumption, high cost efficiency, stability, usability, integration, etc.) and the TMR sensor (also referred to as a tunnel magneto-resistive magnetic sensor, having the characteristics of miniaturization, low cost, low power consumption, high integration, high response frequency and high sensitivity). The power unit can be powered by a button battery, and one button battery can serve for about one year, even longer in a normal state, so that the intelligent module of the present invention is more convenient to use and durable, and the defects of high power consumption, impracticality and trouble of other existing similar devices are overcome. The data obtained by the TMR sensor is transmitted to the low power consumption Bluetooth chip for data processing operation to obtain mileage and other data of the roller skating activity. When the Bluetooth signal of the low power consumption Bluetooth chip is not connected to the terminal device, the processed data can be first stored in the memory, and when the Bluetooth signal is connected to the terminal device, the data is acquired from the memory and transmitted to the terminal device. This detection method is not limited to the moving distance and the device signal, but can accurately transmit the moving distance, thereby effectively eliminating the limitation of GPS positioning on the signal. The acceleration sensor can be used for recording steps of the roller skating shoes, and surveying the skating conditions such as uphill and downhill, which can be programmed in the chip, so that the intelligent module of the roller skating shoes realize more intelligent functions.

Besides that the terminal device can acquire various activity values, its electronic fence unit can also be used for monitoring the range of roller skating activity and giving an alarm, and the over-range alarm function of the electronic fence is realized through the strength of signals transmitted between the low power consumption Bluetooth chip and the Bluetooth transmission unit, so this function is particularly suitable for children's roller skating shoes. A child can skate within the close range of a guardian to prevent losing, so the safety of the roller skating activity can be improved. The electronic pet unit increases a function of virtually feeding a pet, and the roller skating data can be converted into virtual food, thus increasing the roller skating fun, and motivating children to stick to roller skating.

The structure on the wheel carrier is ingenious, the overall appearance is simple, the manufacturing is easy, the circuit board can be well protected, water, dust, collision and damage are avoided, the installation and operation are simple and convenient, and replacement and maintenance are facilitated. With the quick disassembly and assembly clamping structure, the circuit board can be separately removed and used as a portable anti-lost device, and the portable device can continue to acquire activity data and increase application functions.

Based on the above, the intelligent roller skating shoes of the present invention greatly changes the problems of single function and monotonous skating fun of the conventional roller skating shoes, realize more functions, increase the skating fun, are more popular among children, is low in power consumption and unlikely to damage, and can set the safe range of activity to improve the safety of roller skating activity, which is one of the first conditions for parents to choose products.

### BRIEF DESCRIPTION OF THE DRAWINGS

FIG. 1 is a structure diagram of a wheel carrier of intelligent roller skating shoes according to the present invention;

FIG. 2 is an exploded structure diagram of the wheel carrier of the intelligent roller skating shoes according to the present invention;

FIG. 3 is a structural block diagram of a circuit board of the intelligent roller skating shoes according to the present invention;

FIG. 4 is a structural block diagram of a roller skating shoes application software system of the intelligent roller skating shoes according to the present invention.

### DETAILED DESCRIPTION OF THE INVENTION

In order to further interpret the technical solution of the present invention, the following illustrates the present invention in detail through specific embodiments in conjunction with the accompanying drawings.

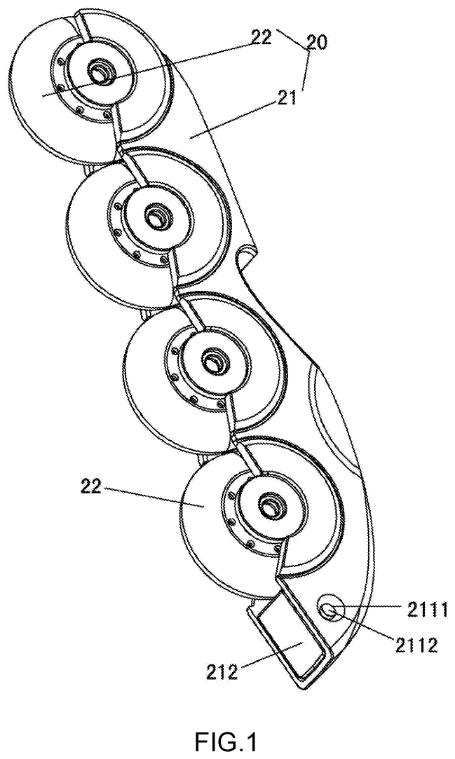

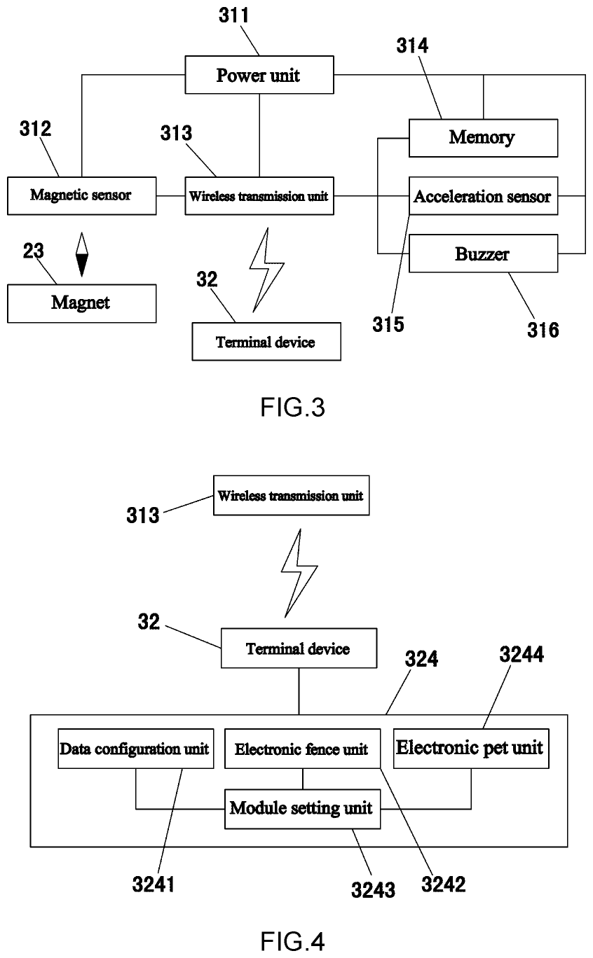

Each of a pair of intelligent roller skating shoes according to the present invention, as shown in FIGS. 1 and 3, includes a shoe body (not shown), a wheel carrier 20, and an intelligent module 30.

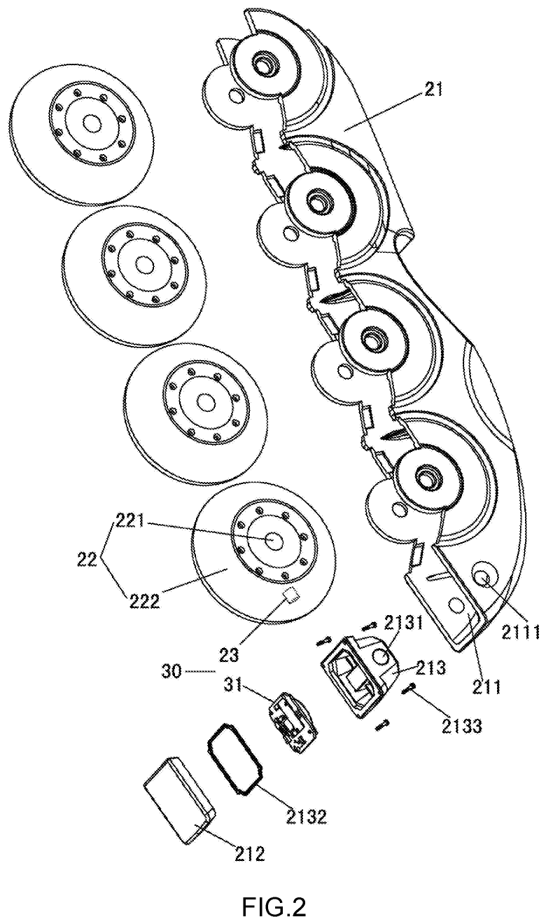

As shown in FIG. 1 and FIG. 2, the wheel carrier 20 is an in-line wheel carrier, and the wheel carrier 20 includes a connecting frame 21 connected to the shoe body and wheels 22 arranged on the connecting frame 21. As shown in FIG. 1, FIG. 2 and FIG. 3, the intelligent effect of the present invention is realized by such a structure as follows.

The wheel 22 is provided with a magnet 23. The magnet 23 is a permanent magnet, so it can be permanently fixedly arranged on the wheel 22. The magnet 23 in the present embodiment is arranged in such a way that the wheel 22 includes a hard axis ring 221 (e.g., a plastic injection molded axis ring) and a rubber rim 222, a fixed arrangement structure for fixedly placing the magnet 23 is arranged on the middle section of the peripheral surface of the axis ring 221, and the rubber rim 222 is injection-molded on the axis ring 211, such that the magnet 23 is embedded into the rubber rim 222, wherein the fixed arrangement structure is not shown in the drawings, and is not limited herein, as long as the magnet 23 can be fixedly placed and not be changed in position when being injection-molded to the rubber rim 222. The fixed arrangement structure arranged on the middle section of the peripheral surface of the axis ring 221 can well position, fix and protect the magnet 23. The middle section here prevents the magnet 23 from being exposed and damaged within two sides, and even protects the magnetism and functions of the magnet 23 from being affected.

The intelligent module 30 includes a circuit board 31 and a terminal device 32 connected by wireless signal transmission. Specifically, the circuit board 31 is arranged on the connecting frame 21, and includes, as shown in FIG. 3, a power unit 311 as well as a magnetic sensor 312, a wireless transmission unit 313, a memory 314, an acceleration sensor 315 and a buzzer 316 connected to the power unit 311 by circuits. The magnetic sensor 312 is connected to the wireless transmission unit 313 by a circuit. The wireless transmission unit 313 in the present embodiment is a low power consumption Bluetooth chip. The low power consumption Bluetooth chip provided with a processor can be used for data processing, and also has the characteristics of low power consumption, high cost efficiency, stability, usability, integration and the like. The magnetic sensor 312 is a TMR sensor, and the TMR sensor is also referred to as a tunnel magneto-resistive magnetic sensor with the characteristics of miniaturization, low cost, low power consumption, high integration, high response frequency and high sensitivity, thereby realizing the above advantages of low power consumption, high sensitivity and the like of the present invention. In the present embodiment, the power unit 311 is powered by a button battery having a small size, and the overall layout structure of the circuit board 31 is also small. The magnetic sensor 312 is arranged corresponding to the magnet 23 of the wheel 22. When the wheel 22 rotates, the magnet 23 can respond to the magnetic sensor 312, thereby sensing the number of revolutions of the wheel 22 and transmitting the same to the low power consumption Bluetooth chip calculates the moving distance of the roller skating shoes, that is, the mileage of the roller skating shoes, from the obtained number of revolutions of the wheel 22 and the perimeter of the wheel 22 by preset data processing program design.

The memory 314 is connected to the power unit 311 and the wireless transmission unit 313 by circuits. The memory 314 can be used for storing data (operation information) processed by the low power consumption Bluetooth chip and data content transmitted by Bluetooth. For example, when the low power consumption Bluetooth chip is not in signal connection with the terminal device 32, the data processed by it is directly stored in the memory 314. When being in signal connection with the terminal device 32, the low power consumption Bluetooth chip transmits the data stored in the memory 314 to the terminal device 32 to ensure that the data is not lost, and also stores firmware upgrade data, operation information, etc.

The acceleration sensor 315 is connected to the power unit 311 and the wireless transmission unit 313 by circuits, can be used for sensing the number of foot lifting (i.e., recording the number of steps) of the roller skating shoes and surveying uphill, downhill, etc., and can realize more functions in combination with firmware program design and roller skating shoes application software. Of course, if these functions are not required, the acceleration sensor 315 is also not required. When being used as a carry-on anti-lost device as described below, the acceleration sensor 315 can be used for recording the number of steps.

The buzzer 316 is connected to the power unit 311 and the wireless transmission unit 313 by circuits for sending an alarm, and of course, can be combined with firmware program design and roller skating shoes application software for voice.

In the present invention, as shown in FIG. 4, the terminal device 32 includes a Bluetooth transmission unit 321, an interactive operation screen (not shown), an intelligent operating system (not shown), and roller skating shoes application software 324 installed and operated in the intelligent operating system. The roller skating shoes application software 324 displays and interacts an operation through the interactive operation screen. The roller skating shoes application software 324 is connected with the low power consumption Bluetooth chip through the Bluetooth transmission unit 321 to transmit data so as to acquire roller skating data of the roller skating shoes. The roller skating shoes application software 324 includes a data configuration unit 3241 for recording the roller skating data in the software and displaying the corresponding data in the interactive operation screen, an electronic fence unit 3242 for setting an activity range and giving an alarm, and a module setting unit 3243 for setting software functions. The electronic fence unit 3242 realizes a fence function by acquiring the signal strength of connection between the Bluetooth transmission unit 321 and the low power consumption Bluetooth chip. The electronic fence unit 3242 sets the activity range, and activates the functions, calculates the distance of the low power consumption Bluetooth chip through the acquired Bluetooth signal strength value, judges whether the roller skating shoes are within the activity range set by the electronic fence, and gives an over-range alarm to catch the attention of the carrier of the terminal device. The buzzer 316 in the circuit board 31 may also be used for over-range alarm to remind the user of exceeding the activity range.

In the present invention, the roller skating shoes application software 324 may further include an electronic pet unit 3244, which can convert the roller skating data into a function of virtually feeding a pet with virtual food. The specific game mode is a software design content, which is not defined here, thus increasing game function and roller skating fun, and motivating children to stick to roller skating. The terminal device 32 in the present invention may be a hand-held device (a mobile phone, a tablet computer, etc.) or a watch device, or the both.

The above structure of the present invention on the wheel carrier 20 is designed as follows. As shown in FIG. 1 and FIG. 2, the magnet 23 is arranged on the wheel 22 closest to the rear end of the roller skating shoes, which is more appropriate because the front end is more susceptible to bump and affects the control on the roller skating technology. The rear end of the connecting frame 21 is extended to form a mounting cavity 211 for fixedly mounting the circuit board 31. A sealing cover 212 for sealing and covering the circuit board 31 is arranged on the mounting cavity 211 to well protect the circuit board 31 from being exposed and damaged. In order to mount and operate the circuit board 31 more simply and conveniently, a detachable mounting shell 213 is embedded into the mounting cavity 211, the circuit board 31 is fixedly embedded in the mounting shell 213, and the sealing cover 212 covers the mounting shell 213. When the roller skating shoes are manufactured, the circuit board 31 can be assembled with the mounting shell 213 and the sealing cover 212 after detection, and mounted on the wheel carrier 20 of the roller skating shoes in the final step. This structural arrangement is also advantageous for later replacement and maintenance. In the present embodiment, the connecting structure between the mounting shell 213 and the connecting frame 21 includes that the mounting shell 213 is provided with a through hole 2131, a side wall of the mounting cavity 211 is provided with a mounting hole 2111 corresponding to the through hole 2131, the mounting shell 213 passes through the mounting hole 2111 and the through hole 2131 through a pin 2112 and is fixedly arranged in the mounting cavity 211, the mounting shell 213 and the sealing cover 212 are sealed by a sealing ring 2132, and the mounting shell 213 and the sealing cover 212 are fixedly connected by screws 2133, so that the connecting structure is sealed and stable.

In the present invention, since the electronic fence function of the set activity range realized between the circuit board 31 and the terminal device 32 can also be used for children's anti-lost use, this part can be used as an anti-lost device as well. For ease of use, a positioning structure and a connecting structure for quick disassembly and assembly (not shown), which match with each other, are respectively arranged in the mounting cavity 211 and on the mounting shell 213. The positioning structure is used for mounting the mounting shell 213 at a fixed position to ensure the normal sensing use of the roller skating activity. The connecting structure for quick disassembly and assembly can realize simple, convenient and quick disassembly and assembly, and can also realize reliable connection and avoid falling off to ensure the normal sensing use of the roller skating activity. In order to ensure that the carry-on component can be placed at the fixed position and is unlikely to fall and lose, the mounting shell 213 or the sealing cover 212 may be further provided with a clamping structure. The clamping structure may be the conventional clamping structure, which is not specifically limited, as long as it facilitates clamping.

What is claimed is:

1. The intelligent roller skating shoes, each comprising a shoe body, a wheel carrier, and an intelligent module, wherein the wheel carrier comprises a connecting frame connected to the shoe body and wheels arranged on the connecting frame, one wheel is provided with a magnet, the intelligent module comprises a circuit board and a terminal device connected by wireless signal transmission, the circuit board comprises a power unit as well as a magnetic sensor and a wireless transmission unit connected to the power unit by circuits, the magnetic sensor is connected to the wireless transmission unit by a circuit, the circuit board is arranged on the connecting frame, the magnetic sensor is arranged corresponding to the magnet of the wheel, and the magnet can respond to the magnetic sensor when the wheel rotates.

2. The intelligent roller skating shoes as in claim 1, characterized in that: the wireless transmission unit is a low power consumption Bluetooth chip, the magnetic sensor is a TMR sensor, the circuit board further comprises a memory and an acceleration sensor, the memory is connected to the power unit and the wireless transmission unit by circuits, and the acceleration sensor is connected to the power unit and the wireless transmission unit by circuits.

3. The intelligent roller skating shoes as in claim 2, characterized in that: the terminal device comprises a Bluetooth transmission unit, an interactive operation screen, an intelligent operating system, and a roller skating shoes application software installed and operated in the intelligent operating system, the roller skating shoes application software displays and interacts an operation through the interactive operation screen, the roller skating shoes application software is connected with the low power consumption Bluetooth chip through the Bluetooth transmission unit to transmit data so as to acquire roller skating data of the roller skating shoes, the roller skating shoes application software comprises a data configuration unit, an electronic fence unit and a module setting unit, and the electronic fence unit realizes a fence function by acquiring the signal strength of connection between the Bluetooth transmission unit and the low power consumption Bluetooth chip.

4. The intelligent roller skating shoes as in claim 3, characterized in that: the circuit board further comprises a buzzer connected to the power unit and the wireless transmission unit by circuits.

5. The intelligent roller skating shoes as in claim 3, characterized in that: the roller skating shoes application software further comprises an electronic pet unit.

6. The intelligent roller skating shoes as in claim 1, characterized in that: the wheel comprises an axis ring and a rubber rim, a fixed arrangement structure for fixedly placing the magnet is arranged on the middle section of the peripheral surface of the axis ring, the rubber rim is injection-molded on the axis ring, and the magnet is embedded into the rubber rim.

7. The intelligent roller skating shoes as in claim 1, characterized in that: wherein the wheel carrier is an in-line wheel carrier, the magnet is arranged on the wheel closest to the rear end of the roller skating shoes, the rear end of the connecting frame is extended to form a mounting cavity for fixedly mounting the circuit board, and a sealing cover for sealing and covering the circuit board is arranged on the mounting cavity.

8. The intelligent roller skating shoes as in claim 7, characterized in that: a detachable mounting shell is embedded into the mounting cavity, the circuit board is fixedly embedded in the mounting shell, and the sealing cover covers the mounting shell.

9. The intelligent roller skating shoes as in claim 8, The mounting shell is provided with a through hole, a side wall of the mounting cavity is provided with a mounting hole corresponding to the through hole, the mounting shell passes through the mounting hole and the through hole through a pin and is fixedly arranged in the mounting cavity, the mounting shell and the sealing cover are sealed by a sealing ring, and the mounting shell and the sealing cover are fixedly connected by screws.

10. The intelligent roller skating shoes as in claim 8, A positioning structure and a connecting structure for quick disassembly and assembly, which match with each other, are respectively arranged in the mounting cavity and on the mounting shell, and the mounting shell or the sealing cover is provided with a clamping structure.
